(19) United States
(12) Patent Application Publication
(10) Pub. No.: US 2006/0231878 A1
(43) Pub. Date: Oct. 19, 2006

(54) Semiconductor device and method for manufacturing same

(75) Inventors: Iwao Shirakawa, Kanagawa (JP); Nobutaka Nagai, Kanagawa (JP); Ryo Kubota, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/408,735

(22) Filed: Apr. 17, 2006

(30) Foreign Application Priority Data
Apr. 18, 2005 (JP) 2005-119305

(51) Int. Cl. H01L 29/94

(52) U.S. Cl. 257/301

(57) ABSTRACT

The semiconductor device 100 includes: a semiconductor substrate 102; a capacitor 116 formed on the semiconductor substrate 102, including a structure composed of a lower electrode 118, a capacitive film 120 and an upper electrode 122, which are stacked in this sequence; an extracting unit 124 of the upper electrode 122 of the capacitor 116; and a contact 108c formed below the extracting unit 124, and providing an electrical coupling between the extracting unit 124 and an underlying interconnect such as an impurity-diffused region 103 and the like.

This application is based on Japanese patent application No. 2005-119,305, the content of which is incorporated hereinto by reference.

### BACKGROUND

1. Technical Field

The present invention relates to a semiconductor device including a capacitance and a method for manufacturing thereof.

2. Related Art

A capacitor element is composed of a lower electrode, a capacitive insulating film formed thereon, and an upper electrode formed thereon. In a dynamic random-access memory (DRAM), there has been a problem in the conventional configuration that an aspect ratio of a contact for extracting an electric potential from a lower electrode to the outside is different from an aspect ratio of a contact for maintaining an uniformity electric potential in an upper electrode. Therefore, there are drawbacks occurred in forming the contact for maintain a uniformity electric potential in the upper electrode that punching through is caused by the etching, and/or a difficulty is caused in the control of a film thickness of a barrier metal formed on a bottom of a contact hole.

Japanese Laid-Open Patent Publication No. 2000-294,749 discloses a semiconductor memory device, which is capable of preventing such punching through of the contact hole and/or an instability of the contact resistance. Such semiconductor memory device includes: an interlayer insulating film; a cylindrical lower electrode formed in the interlayer insulating film; a capacitive insulating film formed on an inner surface of the lower electrode; an upper electrode formed so as to face the lower electrode across the capacitive insulating film; a cylindrical trench formed in the interlayer insulating film; an extracting unit formed on the inner surface of the trench; an upper electrode-elongating unit for providing an electrical coupling between the upper electrode and the extracting unit; an upper electrode contact formed on the interlayer insulating film and coupled to the extracting unit on the bottom of the trench; and an upper electrode interconnect formed on the interlayer insulating film and coupled to the upper electrode contact. Such configuration provides an increased aspect ratio of the contact for the upper electrode, thereby reducing differences in the aspect ratio between the contact for the lower electrode and other contacts. Therefore, a punching through the extracting unit can be prevented in the etching process for forming the contact dedicated for the upper electrode, and when a barrier metal is formed on the bottom surface of the contact hole dedicated for the upper electrode, the film thickness can be uniformly controlled, thereby providing an appropriate control of the contact resistance in the contact.

In the meantime, it is considered that the miniaturization of the semiconductor device is more progressed in the future. It is also considered that the miniaturization causes, in turn, changes in materials for an electrode of a capacitor. In such case, following problems are caused, when the contact for the upper electrode is formed above the upper electrode.

For example, when a material exhibiting lower etch selectivity over an insulating film in which a contact hole is formed is employed for an electrode material of the capacitor, even if differences in aspect ratio between the contact for the upper electrode and other contacts are smaller, there is also a fear for causing a punching through in the etching process. In addition, the upper electrode may be damaged when the contact for the upper electrode is formed, regardless of the type of the electrode material of the capacitor, and therefore there is a fear that an increase in the contact resistance and/or a failure in the open may be created, thereby reducing a production yield. Further, even if a material exhibiting higher etch selectivity over the insulating film that is to be provided with a contact hole is employed for the electrode material of the capacitor, various investigations for appropriately selecting etching conditions should be conducted in order to prevent a punching through the upper electrode, and therefore the process requires much time and manpower.

### SUMMARY OF THE INVENTION

According to one aspect of the present invention, there is provided a semiconductor device, including: a semiconductor substrate; a capacitor formed on the semiconductor substrate, the capacitor having a stacked structure including a lower electrode, a capacitive film and an upper electrode, that are stacked in this sequence; an extracting unit of the upper electrode of the capacitor; and a first contact formed under the extracting unit, and providing an electrical coupling between the extracting unit and a first underlying interconnect.

Since the first contact, which is capable of providing an electrical coupling between the extracting unit and a first underlying interconnect, is formed under the extracting unit according to the above-described aspect of the present invention, a formation of the extracting unit can be conducted after forming the contact, and therefore an increase in the contact resistance or a failure in the open can be inhibited in the formation of the first contact, without damaging the extracting unit.

According to another aspect of the present invention, there is provided a method for manufacturing a semiconductor device, including: forming an insulating film on an underlying interconnect that is formed on a surface of or above a semiconductor substrate; forming a contact in the insulating film, the contact being electrically coupled to the underlying interconnect; forming a multiple-layered structure in a region on the insulating film which is different from the region where the contact is formed, the multiple-layered structure being composed of a lower electrode and a capacitive film, which are stacked in this sequence; and forming an upper electrode material on the insulating film, the upper electrode material covering the capacitive film and being coupled to the contact.

Since a formation of the upper electrode material can be conducted after forming the contact, an increase in the contact resistance or a failure in the open can be inhibited in the formation of the contact, without damaging the upper electrode. In addition, according to the present invention, the contact can be formed without a need for preparing for a special mask data or designing a layout.

As described above, according to the present invention, damage to the upper electrode can be avoided in the formation of the contact for the upper electrode of the capacitor, thereby preventing an increase in the contact resistance or a decrease in a production yield.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view, illustrating a configuration of a semiconductor device in a first embodiment of the present invention;

FIGS. 2A to 2C are cross-sectional views of a semiconductor device, illustrating a procedure for manufacturing the semiconductor device in the first embodiment of the present invention;

FIGS. 3A and 3B are cross-sectional views of the semiconductor device, illustrating the procedure for manufacturing the semiconductor device in the first embodiment of the present invention;

FIG. 4 is a cross-sectional view, illustrating another configuration of a semiconductor device in the first embodiment of the present invention;

FIG. 5 is a cross-sectional view, illustrating a configuration of a semiconductor device in a second embodiment of the present invention;

FIGS. 6A to 6C are cross-sectional views of a semiconductor device, illustrating a procedure for manufacturing the semiconductor device in the second embodiment of the present invention;

FIG. 7 is a cross-sectional view, illustrating another configuration of a semiconductor device in the second embodiment of the present invention;

FIG. 8 is a cross-sectional view, illustrating a configuration of a semiconductor device in a third embodiment of the present invention;

FIG. 9 is a cross-sectional view, illustrating another configuration of a semiconductor device in the third embodiment of the present invention;

FIG. 10 is a cross-sectional view, illustrating a configuration of a semiconductor device in a fourth embodiment of the present invention;

FIG. 11 is a cross-sectional view, illustrating another configuration of a semiconductor device in the fourth embodiment of the present invention; and

FIG. 12 is a plan view, illustrating a configuration of an upper electrode and an extracting unit in an embodiment of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments according to the present invention will be described as follows in further detail, in reference to the annexed figures. In all figures, identical numeral is assigned to an element commonly appeared in the figures, and the detailed description thereof will not be presented. A semiconductor device employed in the present embodiment is a mixed-mounting device that includes a dynamic random access memory (DRAM) unit and a logic unit.

### FIRST EMBODIMENT

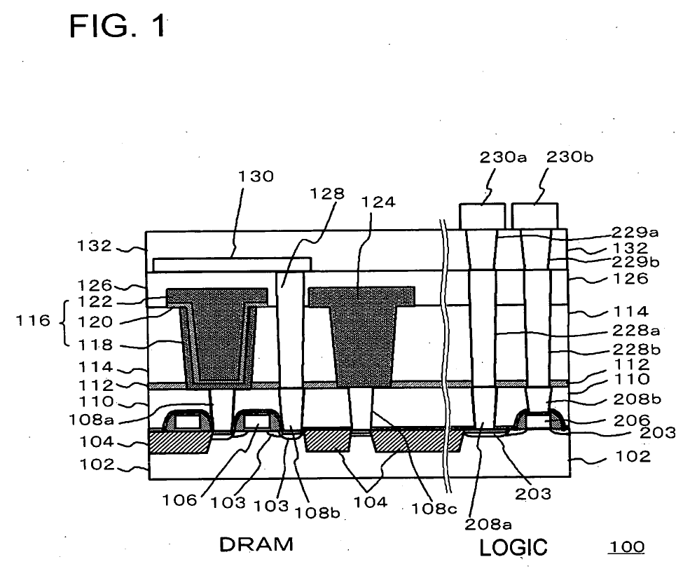

FIG. 1 is a cross-sectional view, illustrating a configuration of a semiconductor device in the present embodiment. In this embodiment, a logic unit having a transistor or the like formed therein and a DRAM unit having a capacitor formed therein are formed on the semiconductor substrate 102 of the semiconductor device 100. The semiconductor device 100 includes: a semiconductor substrate 102; a capacitor 116 formed on the semiconductor substrate 102, including a structure composed of a lower electrode 118, a capacitive film 120 and an upper electrode 122, which are stacked in this sequence; an extracting unit (or extracting electrode) 124 of the upper electrode 122 of the capacitor 116; and a contact 108c formed below the extracting unit 124 and providing an electrical coupling between the extracting unit 124 and an underlying interconnect such as an impurity-diffused region 103 and the like.

The semiconductor device 100 includes a semiconductor substrate 102 composed of a silicon substrate for example, a first insulating film 110 formed thereon, an etch stop film 112 formed thereon, a second insulating film 114 formed thereon, a third insulating film 126 formed thereon, and a fourth insulating film 132 formed thereon.

In the logic unit, the semiconductor device 100 includes an impurity-diffused region 203 formed in the semiconductor substrate 102, a gate 206 formed on the semiconductor substrate 102, a contact 208a and a contact 208b, which are formed in the first insulating film 110, a contact 228a and a contact 228b, which are formed in the second insulating film 114 and in the third insulating film 126, a contact 229a and a contact 229b, which are formed in the fourth insulating film 132, and an interconnect 230a and an interconnect 230b, which are formed on the fourth insulating film 132. Here, the interconnect 230b is electrically coupled to the gate 206, via the contact 229b, the contact 228b and the contact 208b. In addition, the interconnect 230a is electrically coupled to the impurity-diffused region 203 via the contact 229a, the contact 228a and the contact 208a. A transistor is formed by the gate 206 and impurity-diffused regions 203 formed in each side thereof.

In the DRAM unit, the semiconductor device 100 includes an impurity-diffused region 103 and a device isolation region 104, which are formed in the semiconductor substrate 102, a gate 106 formed on the semiconductor substrate 102, a contact 108a a contact 108b, and a contact 108c, which are formed in the first insulating film 110, a capacitor 116 and an extracting unit 124, which are formed in the second insulating film 114, a contact 128 formed in the second insulating film 114 and the third insulating film 126, and a bit line 130 formed on the third insulating film 126. Here, the capacitor 116 may be a metal-insulator-metal (MIM) capacitor. A capacitor 116 includes the lower electrode 118, the capacitive film 120, and the upper electrode 122. Here, the bit line 130 is electrically coupled to the impurity-diffused region 103 via the contact 128 and the contact 108b. In addition, the lower electrode 118 of the capacitor 116 is electrically coupled to the impurity-diffused region 103 via the contact 108a. A transistor is formed by the gate 106 and impurity-diffused regions 103 formed in each side thereof.

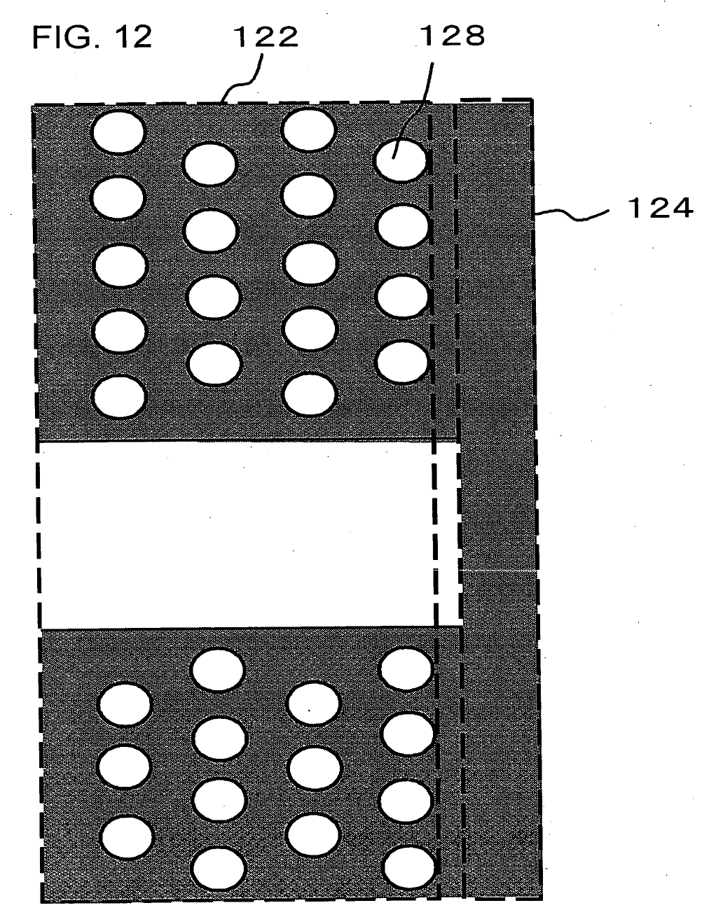

Although it is not shown here, the upper electrode 122 and the extracting unit 124 are formed to be mutually electrically coupled. FIG. 12 is a plan view, illustrating a configuration of the upper electrode 122 and the extracting unit 124. As shown in FIG. 12, the upper electrode 122 is formed over the entire regions except the region where contacts, for example, the contacts 128 are formed in the DRAM unit, and a portion thereof functions as the extracting unit 124. Returning to FIG. 1, the extracting unit 124 is electrically coupled to the impurity-diffused region 103 formed in the semiconductor substrate 102 via the contact 108c. According to the semiconductor device 100 in the present embodiment, an electrical coupling to the upper electrode 122 can be achieved via the contact formed below the upper electrode plate, which is composed of the upper electrode 122 and the extracting unit 124.

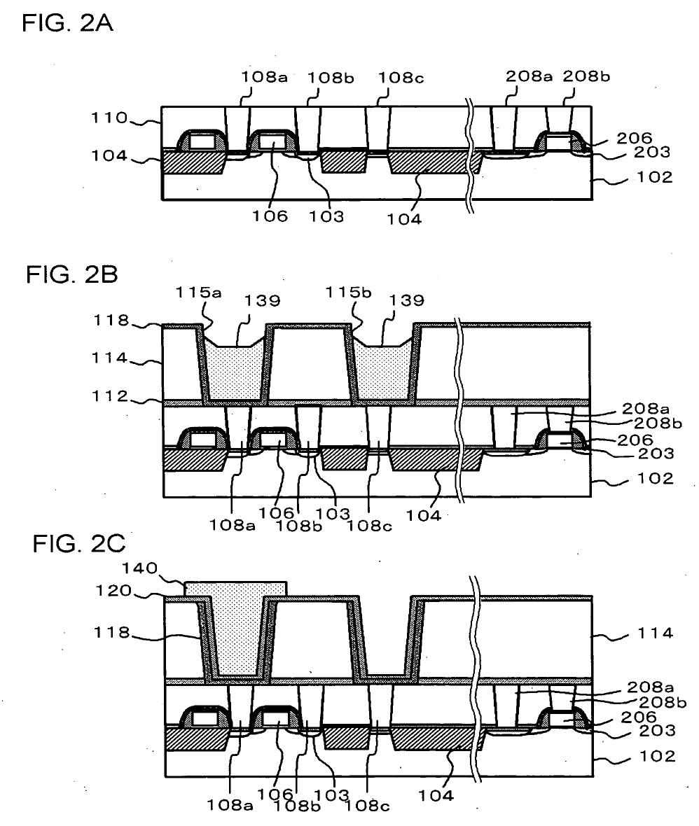

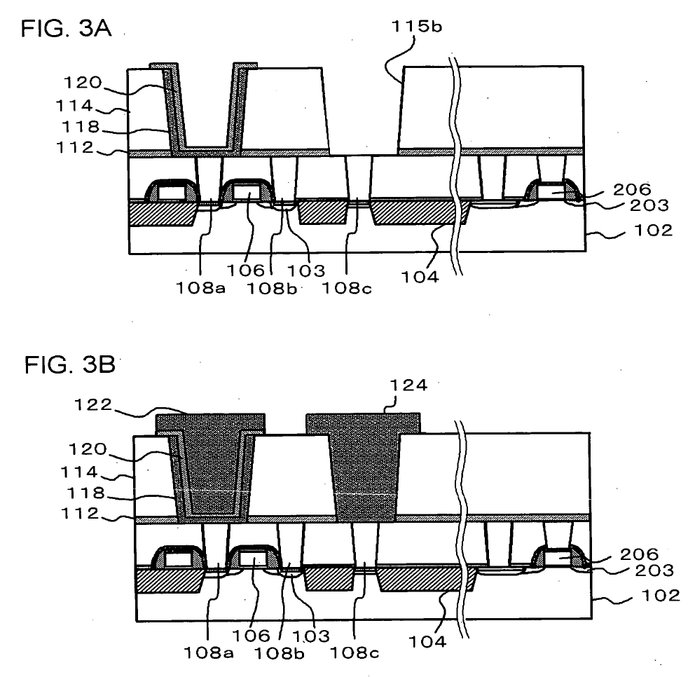

FIGS. 2A to 2C and FIGS. 3A and 3B are process cross-sectional views, illustrating a procedure for manufacturing the semiconductor device in the present embodiment.

A method for manufacturing the semiconductor device 100 in the present embodiment includes: forming the first insulating film 110 on the impurity-diffused region 103 that is formed on the surface of or above the semiconductor substrate 102; forming in the first insulating film 110 the contact 108c coupled to the impurity-diffused region 103; forming, in a region in the insulating film 110, which is different from the region where the contact 108c is formed, a multiple-layered structure, which is composed of the lower electrode 118 and the capacitive film 120 that are stacked in this sequence; and forming on the first insulating film 110 the upper electrode material which covers the capacitive film 120 and is coupled to the contact 108c. The process will be explained in more detail in the following.

First of all, a device isolation region 104 is formed in the semiconductor substrate 102 via a shallow trench isolation (STI) process. The device isolation region 104 is formed as follows. First, a concave portion for forming the device isolation region 104 is formed in the semiconductor substrate 102. Subsequently, a silicon oxide film is formed via a chemical vapor deposition (CVD) process on the entire surface of the semiconductor substrate 102 so as to fill the concave portion. Thereafter, exposed portions of the insulating film, which are located outside of the concave portion, are remove via a chemical mechanical polishing (CMP) process. Having such procedure, the device isolation region 104 is formed.

Subsequently, a silicon oxide film is formed on the entire surface of the semiconductor substrate 102 via a thermal processing. Then, a polysilicon film is formed on the silicon oxide film via the CVD process. Then, the polysilicon film is patterned by utilizing a lithographic technology. Having this procedure, the gate 206 and the gate 106 are formed in the logic unit and in the DRAM unit, respectively. Thereafter, an ion implantation process is conducted over the semiconductor substrate 102 via a mask of the gate 106 and the gate 206, so that the impurity-diffused regions 103 and the impurity-diffused regions 203, which will function as source or drain, respectively, are formed in each side of the gate 106 and the gate 206, respectively. Having this procedure, transistors are formed in the DRAM unit and in the logic unit, respectively.

Subsequently, the first insulating film 110 (having a film thickness of about 300 nm to 600 nm) is formed on the entire surface of the semiconductor substrate 102 via a CVD process. The first insulating film 110 may be composed of, for example, boro-phospho-silicate glass (BPSG). In addition, before forming the first insulating film 110, an etch stop film, which may be composed of, for example, a silicon nitride film, may be formed on the entire surface of the semiconductor substrate 102 via a CVD process. Then, a resist having a certain geometry (not shown) is formed on the first insulating film 110, and then, contact holes for forming the contact 108a, the contact 108b and the contact 108c those extend to the impurity-diffused regions 103, for forming the contact 208a that extends to the impurity-diffused region 203, and for forming the contact 208b that extends to gate 206, are formed through a mask of the formed resist in the first insulating film 110. Thereafter, the resist is stripped. Subsequently, an electrically conducting film is formed on the entire surface of the semiconductor substrate 102 to fill the contact holes therewith. Here, the electrically conducting film for forming the contacts may be composed of, for example, a metal such as W, or polysilicon. Then, exposed portions of the electrically conducting film, which are located outside of the contact holes, are remove via the CMP process. Having such procedure, the contact 108a, the contact 108b and the contact 108c are formed in the DRAM unit, and the contact 208a and the contact 208b are formed in the logic unit (FIG. 2A).

Thereafter, the etch stop film 112 and the second insulating film 114 (having a film thickness of about 800 nm to 1600 nm) are formed on the entire surface of the semiconductor substrate 102 via the CVD process. The etch stop film 112 may be composed of, for example, an SiON film. The second insulating film 114 may be composed of, for example, a silicon oxide film. Then, a concave portion 115a and a concave portion 115b are formed in regions of the second insulating film 114 and the etch stop film 112 disposed above the contact 108a and the contact 108c by utilizing a lithographic technology employing a resist, thereby exposing the contact 108a and the contact 108c. In the present embodiment, a capacitor is formed to have a cylindrical shape. Therefore, the concave portion 115a and the concave portion 115b are also formed to have the cylindrical shape. Here, the cylinder diameter of the capacitor may be selected to be, for example, about 0.24 μm.

Subsequently, the lower electrode 118 (having a film thickness of about 10 nm to 30 nm) is formed on the entire surface of the semiconductor substrate 102. The lower electrode 118 may be composed of, for example, titanium nitride (TiN); a layered structure of titanium/titanium nitride (Ti/TiN); tantalum nitride (TaN); tungsten nitride (WN); platinum (Pt); ruthenium (Ru); or polysilicon. In the present embodiment, the lower electrode 118 may be composed of TiN formed via a metal organic CVD (MOCVD) process utilizing a precursor such as tetrakis-dimethylamido-titanium (Ti(NMe₂)₄) and the like. Alternatively, in other exemplary implementations, the lower electrode 118 may also be deposited via an atomic layer deposition (ALD) process. Further, a layer composed of Ti (having a film thickness of about 10 nm) may be formed as a layer underlying the lower electrode 118, depending on the material of the lower electrode 118 that is coupled to the contact 108a.

Thereafter, in order to protect the lower electrode 118 formed in the concave portion 115a and the concave portion 115b, a resist 139 is formed in the concave portion 115a and the concave portion 115b (FIG. 2B). The resist 139 may be formed by, first, applying a resist film over the entire surface of the substrate, and then conducting an exposure process so as to partially leave the resist in the interiors of the concave portion 115a and the concave portion 115b.

Subsequently, the exposed portions of the lower electrode 118 located outside of the concave portion 115a and the concave portion 115b are removed via an etch process. Thereafter, the capacitive film 120 (having a film thickness of several nm) is formed on the entire surface of the semiconductor substrate 102. The capacitive film 120 may be compose of, for example, high dielectric constant materials such as tantalum (Ta) compound such as Ta₂O₅, TaON and the like, zirconium (Zr) compound such as ZrO₂ and the like and hafnium (Hf) compound such as HfSiO and the like, or a silicon nitride film. In the present embodiment, the capacitive film 120 may be composed of Ta₂O₅. After forming the Ta₂O₅ film, a plasma oxidization processing may be conducted. This processing provides an oxidization of the capacitive film 120 and a removal of impurities. The plasma oxidization processing may be conducted by utilizing N₂ gas and O₂ gas at a temperature within a range of from about 300 degree C to 500 degree C for about 1 minute to 5 minutes. Alternatively, in another exemplary implementation, an ultra violet ray-ozone gas (UV-O₃) processing may be conducted, in place of the plasma oxidization processing.

Thereafter, in order to remove the lower electrode 118 and the capacitive film 120 formed in the concave portion 115b, and other unwanted portions of the capacitive film 120, a resist 140 for protecting the rest of the regions other than these unwanted portions is formed (FIG. 2C). The resist 140 is formed to cover the concave portion 115a.

Thereafter, an etch process is conducted through a mask of the resist 140 to remove the lower electrode 118 and the capacitive film 120 in the concave portion 115b and the like. Subsequently, the resist 140 is removed (FIG. 3A).

Subsequently, similarly as the formation of the lower electrode 118, an upper electrode material (having a film thickness of about 30 nm to 50 nm) is formed on the entire surface of the semiconductor substrate 102 via a MOCVD process. The upper electrode material may be composed of the same material as employed for composing the lower electrode 118, or of a different material therefrom. The upper electrode material may be, for example, TiN, TaN, WN, Pt, Ru or polysilicon. In the present embodiment, the upper electrode material may be composed of TiN formed via a MOCVD process utilizing a precursor such as Ti(NMe₂)₄ and the like. Alternatively, in other exemplary implementations, the upper electrode material may also be deposited via an atomic layer deposition process. Further, a layer composed of Ti (having a film thickness of about 10 nm) may be formed as a layer underlying the upper electrode material, depending on the material of capacitive film 120.

Hereafter, the upper electrode material is patterned by utilizing a lithographic technology to form the upper electrode 122 and the extracting unit 124 (FIG. 3B). Although it is shown in FIG. 3B that the upper electrode 122 is not coupled to the extracting unit 124, these are mutually coupled physically, and further electrically coupled, via other portions, as described in FIG. 12.

Further description will be made in reference to FIG. 1. Subsequently, the third insulating film 126 is formed on the entire surface of the semiconductor substrate 102. The third insulating film 126 may be composed of, for example, silicon oxide film. Then, a lithographic technology is utilized to form a contact hole extending to the contact 108b in the DRAM unit, and to form contact holes extending to the contact 208a and the contact 208b in the logic unit, respectively. Thereafter, an electrically conducting film is formed on the entire surface of the semiconductor substrate 102 to fill these contact holes therewith. Subsequently, the exposed portions of the electrically conducting film disposed outside of the contact hole are removed via the CMP. Having such procedure, the contact 128 is formed in the DRAM unit, and the contact 228a and the contact 228b are formed in the logic unit, respectively. Then, the bit line 130 having a certain pattern is formed on the third insulating film 126. Thereafter, the fourth insulating film 132 is formed on the entire surface of semiconductor substrate 102.

Subsequently, in the logic unit, contact holes extending to the contact 228a and the contact 228b are formed in the fourth insulating film 132 via a lithographic technology. Then, an electrically conducting film is formed on the entire surface of the semiconductor substrate 102 to fill these contact holes therewith. Thereafter, the exposed portions of the electrically conducting film located outside of the contact holes is removed via the CMP. Having such procedure, the contact 229a and the contact 229b are respectively formed in the logic unit. Subsequently, the interconnect 230a and the interconnect 230b respectively having certain patterns are formed on the fourth insulating film 132. Having such procedure, the semiconductor device 100 having the configuration shown in FIG. 1 is obtained. While the configuration having the concave portion 115b filled with the extracting unit 124 is illustrated in FIG. 1, an alternative configuration, in which the extracting unit 124 is formed only on the bottom and the side wall of the concave portion 115b, may also be employed. Any other configurations of the extracting unit 124 may also be employed, as far as an electrical coupling between the contact 108c and the upper electrode 122 is achieved.

In addition, while the exemplary implementation of removing the lower electrode 118 in the concave portion 115b is illustrated in the above-described process shown in FIG. 3A, an alternative configuration of selectively removing only the capacitive film 120 without removing the lower electrode 118 in the concave portion 115b may also be employed. In this case, the lower electrode 118 left in the concave portion 115b may serve as the extracting unit 124.

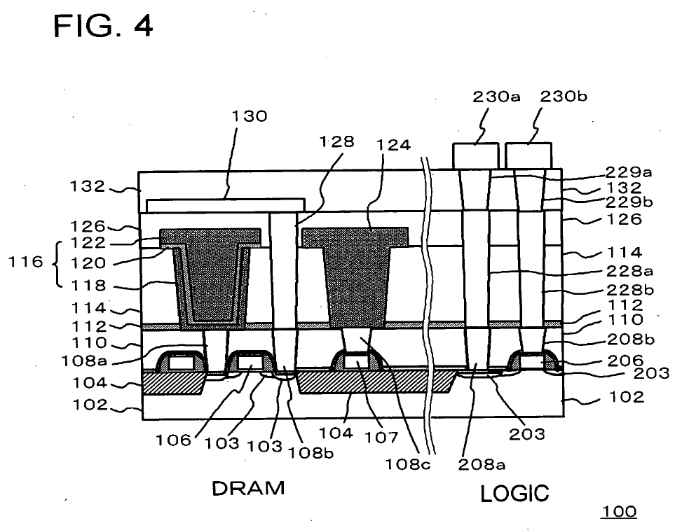

FIG. 4 is a cross-sectional view, illustrating another configuration of a semiconductor device 100 in the present embodiment. Here, the underlying interconnect for coupling the contact 108c to the extracting unit 124 may be a word line. The contact 108c coupled to the extracting unit 124 is coupled to the gate 107, which is a word line formed below the extracting unit 124. As such, the electrical coupling to the extracting unit 124 may also be conducted through the word line.

According to the method for manufacturing the semiconductor device 100 in the present embodiment, a contact for providing a coupling to the upper electrode 122 is formed below the extracting unit 124, which is formed simultaneously with forming the upper electrode 122. Therefore, a punching through or a damage of the extracting unit 124 caused by the etching for forming the contact holes dedicated to the contacts can be avoided. Therefore, a decrease in a production yield of the devices due to an increase in the contact resistance and/or a failure in the open can be avoided. Having such procedure, a stable production yield of the devices can be assured.

Further, when the DRAM unit and the logic unit are formed on the same semiconductor substrate, further problem is occurred in the semiconductor device that an aspect ratio of the contact in the DRAM unit is different from an aspect ratio of the contact in the logic unit, which adversely affect the design of the device, when an electrical contact is to be formed from the above of the upper electrode as in the conventional configuration. In such case, as described above, it is required to employ a material exhibiting larger etch selectivity to the insulating film for forming the contact hole as the electrode material. Since the extracting unit 124 is formed after forming the contact according to the method for manufacturing the semiconductor device in the present embodiment, various types of materials can be employed as the upper electrode material. Another problem is occurred even if a material exhibiting larger etch selectivity to the insulating film for forming the contact hole is employed as the electrode material, that suitable etch conditions for utilizing such larger etch selectivity must be determined. According to the semiconductor device 100 in the present embodiment, such complex procedure can be avoided.

Since the extracting unit 124 can be formed in a procedure same as that for forming the capacitor 116, and also can be formed by selectively removing the portions of the capacitive film 120 formed on certain regions thereof, the semiconductor device 100 in the present embodiment can be manufactured without a need for employing considerably increased number of the manufacturing steps.

### SECOND EMBODIMENT

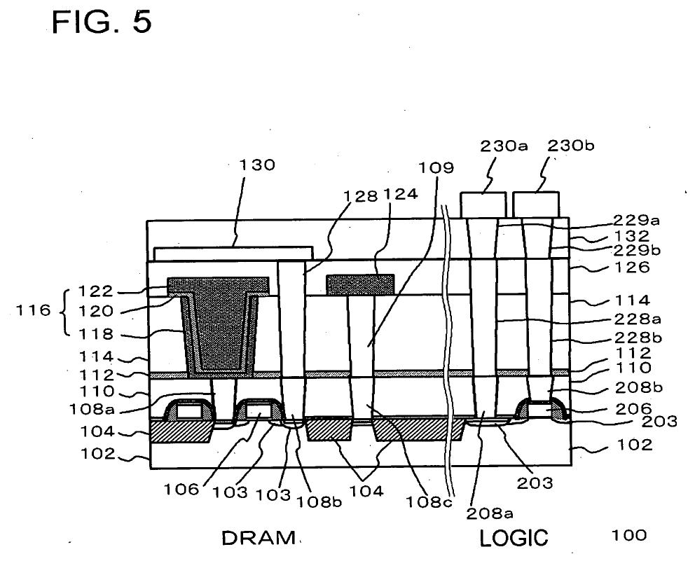

FIG. 5 is a cross-sectional view, illustrating a configuration of a semiconductor device 100 in the present embodiment. A difference lies between the device of the present embodiment and the device of the first embodiment that the extracting unit 124 is formed on the second insulating film 114, and not in the concave portion formed in the second insulating film 114.

The semiconductor device 100 of the present embodiment has substantially same configuration as that of the semiconductor device 100 in the first embodiment described in reference to FIG. 1, except that a contact 109 formed in the second insulating film 114 is further included in the DRAM unit. The contact 109 provides an electrical coupling between the contact 108c and the extracting unit 124.

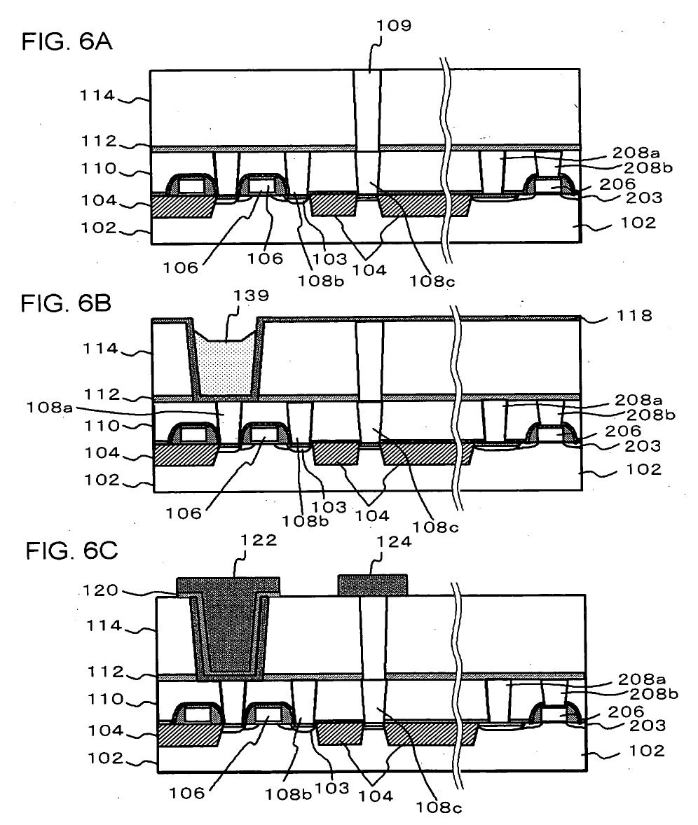

FIGS. 6A to 6C are cross-sectional views of a device, illustrating a procedure for manufacturing the semiconductor device 100 in the present embodiment. First of all, a semiconductor device having the structure shown in FIG. 2A is formed in a similar procedure as described in the first embodiment. Subsequently, the etch stop film 112 and the second insulating film 114 are formed on the entire surface of the semiconductor substrate 102 via a CVD process. Then, a contact hole is formed in regions of the second insulating film 114 and the etch stop film 112 disposed above the contact 108c by utilizing a lithographic technology employing a resist, thereby exposing the contact 108c. Subsequently, an electrically conducting film is formed on the entire surface of the semiconductor substrate 102 to fill the contact hole therewith. Then, exposed portions of the electrically conducting film located outside of contact hole are removed by a CMP process. Having such procedure, the contact 109 is formed in the DRAM unit (FIG. 6A).

Thereafter, a concave portion is formed in the regions of the second insulating film 114 and the etch stop film 112 disposed above the contact 108a to expose the contact 108a.

Subsequently, the lower electrode 118 is formed on the entire surface of the semiconductor substrate 102. Thereafter, for the purpose of providing a protection to the lower electrode 118 formed in the concave portion, a resist 139 is formed in the concave portion (FIG. 6B).

Subsequently, the exposed portions of the lower electrode 118 located outside of the concave portion is removed via an etching process. Thereafter, the capacitive film 120 is formed on the entire surface of the semiconductor substrate 102. Thereafter, unwanted portions of the capacitive film 120 are removed via a lithographic technology employing a resist.

Subsequently, an upper electrode material is formed on the entire surface of the semiconductor substrate 102 via the CVD process. Hereafter, the upper electrode material is patterned to form the upper electrode 122 and the extracting unit 124 (FIG. 6C). Although it is shown in FIG. 6C that the upper electrode 122 seems not coupled to the extracting unit 124, these are physically coupled, and further electrically coupled, via other portions, as shown in FIG. 12. Procedures hereinafter are conducted by similar process as in first embodiment, and therefore descriptions thereof are not repeated.

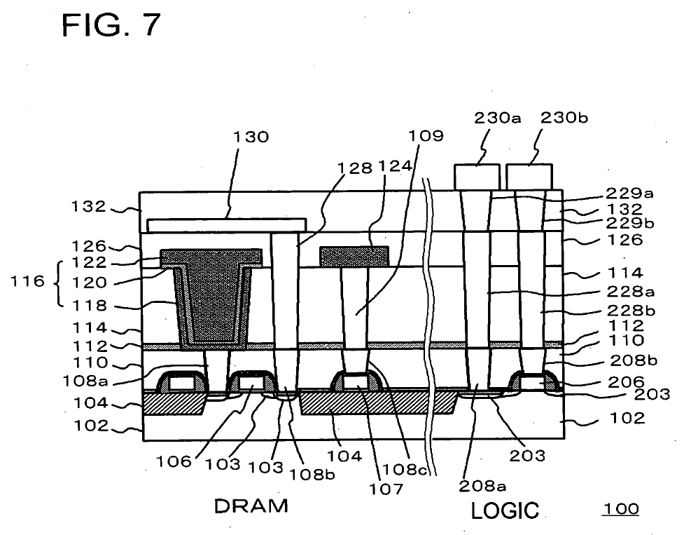

FIG. 7 is a cross-sectional view, illustrating another configuration of a semiconductor device 100 in the present embodiment. Here, the contact 108c, which is electrically coupled to the extracting unit 124, is coupled to the gate 107 that is the word line formed below thereof. As such, the electrical coupling to the extracting unit 124 can also be made through the word line.

In the present embodiment, similar advantageous effect as obtained in first embodiment can be obtained.

### THIRD EMBODIMENT

While the configuration having the bit line 130 formed in the layer above the layer having the capacitor 116 therein is illustrated in the first embodiment, a difference lies between the device of the present embodiment and the device of the first embodiment that the bit line 130 is formed in a layer below the layer having the capacitor 116 therein. In addition, two capacitors 116 of the semiconductor device 100 are shown here.

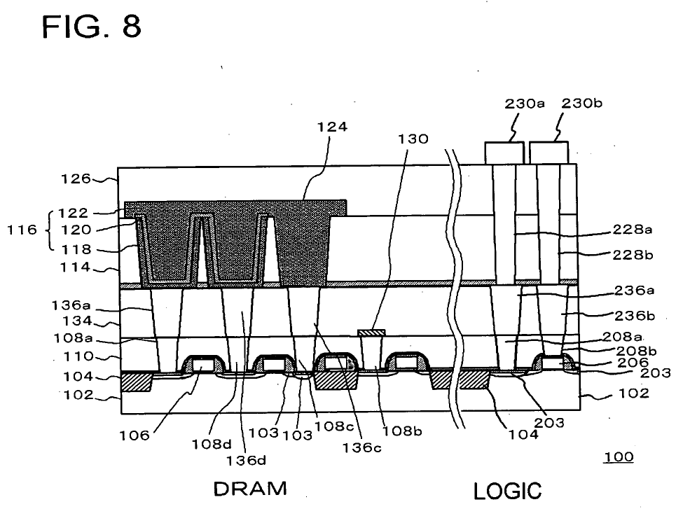

FIG. 8 is a cross-sectional view, illustrating a configuration of a semiconductor device in the present embodiment.

The semiconductor device 100 further includes a fifth insulating film 134 formed between the first insulating film 110 and the second insulating film 114. In addition, in the DRAM unit, the semiconductor device 100 further includes a contact 108d formed in the first insulating film 110, and a contact 136a, a contact 136c and a contact 136d, which are formed in the fifth insulating film 134. The contact 136a provides an electrically coupling between the contact 108a and the lower electrode 118 of one of the capacitors 116. The contact 136d provides an electrically coupling between the contact 108d and the lower electrode 118 of one of the capacitors 116. The contact 136c provides an electrically coupling between the contact 108c and the extracting unit 124. The extracting unit 124 is coupled to the upper electrode 122 of the capacitor 116.

In addition, in the present embodiment, the bit line 130 is formed on the first insulating film 110. The fifth insulating film 134 is formed on the bit line 130.

Further, in the logic unit, the semiconductor device 100 further includes a contact 236a and a contact 236b, which are formed in the fifth insulating film 134. The contact 236a provides an electrically coupling between the contact 208a and the contact 228a. The contact 236b provides an electrically coupling between the contact 208b and the contact 228b.

In the semiconductor device 100 in the present embodiment, the extracting unit 124 can be formed in a procedure same as that for forming the capacitor 116, and also can be formed by selectively removing the portions of the capacitive film 120 formed on certain regions thereof. Thus, the semiconductor device 100 can be manufactured without a need for employing considerably increased number of the manufacturing steps.

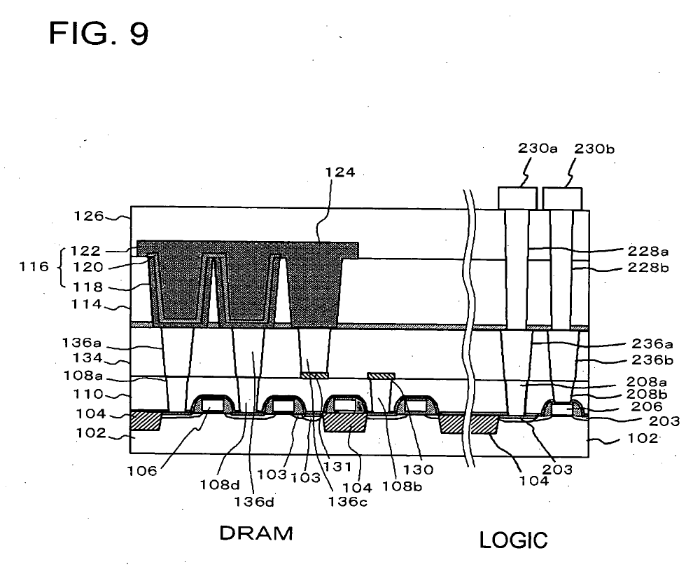

FIG. 9 is a cross-sectional view, illustrating another configuration of the semiconductor device 100 in the present embodiment. Here, an underlying interconnect to which the contact 136c couple the extracting unit 124 electrically may be a bit line. The contact 136c, which is coupled to the extracting unit 124, is coupled to the bit line 131 formed below thereof. As such, the electrical coupling to the extracting unit 124 can also be made through the bit line.

Alternatively, in the present embodiment, the electrical coupling to the extracting unit 124 can also be made through the word line as described referring to FIG. 4 in the first embodiment.

In the present embodiment, similar advantageous effect as obtained in first embodiment can be obtained.

### FOURTH EMBODIMENT

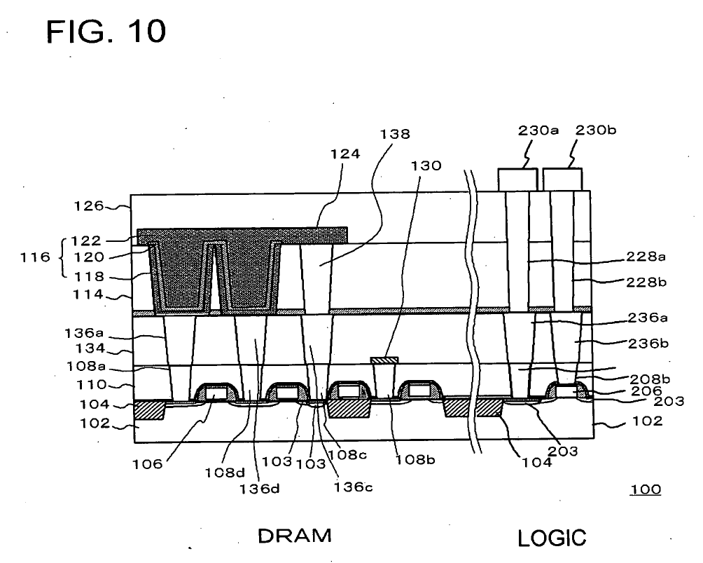

FIG. 10 is a cross-sectional view, illustrating a configuration of a semiconductor device 100 in the present embodiment. A difference lies between the device of the present embodiment and the device of the second embodiment that the bit line 130 is formed in a layer below the layer having the capacitor 116 therein. In addition, two capacitors 116 of the semiconductor device 100 are shown here. A difference lies between the device of the present embodiment and the device of the third embodiment that the extracting unit 124 is formed on the second insulating film 114, and not formed in the concave portion formed in the second insulating film 114.

The semiconductor device 100 of the present embodiment has substantially same configuration as that of the semiconductor device 100 in the third embodiment described in reference to FIG. 8, except that the device further includes a contact 138 formed in the second insulating film 114 in the DRAM unit. The contact 138 provides an electrically coupling between the contact 136c and the extracting unit 124.

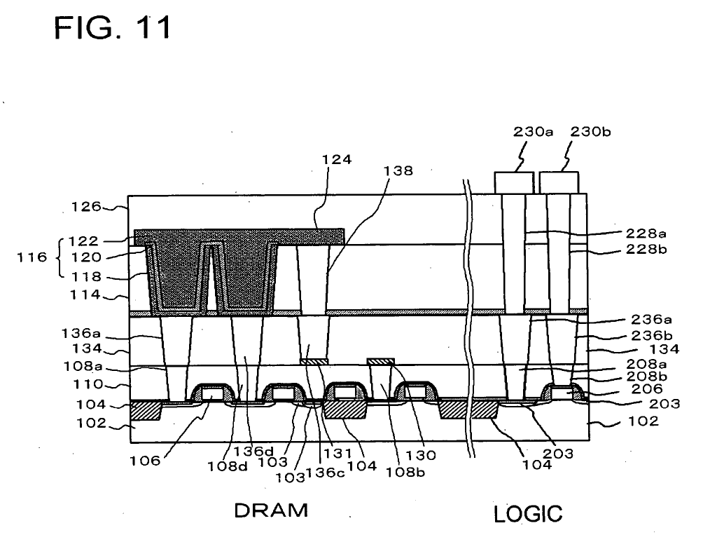

FIG. 11 is a cross-sectional view, illustrating another configuration a semiconductor device 100 in the present embodiment. Here, the contact 136c, which is electrically coupled to the extracting unit 124, is coupled to the bit line 131 formed below thereof. As such, the electrical coupling to the extracting unit 124 can also be made through the bit line.

Alternatively, in the present embodiment, the electrical coupling to the extracting unit 124 can also be made through the word line.

In the present embodiment, similar advantageous effect as obtained in first embodiment can be obtained.

While the preferred embodiments of the present invention have been described above in reference to the annexed figures, it should be understood that the disclosures above are presented for the purpose of illustrating the present invention, and various configurations other than the above described configurations can also be adopted.

While the cylinder-shaped capacitor is illustrated in the above-mentioned embodiment, the present invention is not limited to the cylinder-shaped capacitor, and the present invention may also be applied to other type of capacitor such as, for example, a stacked-type capacitor.

In addition, while the configuration of employing a material that exhibits lower etch selectivity to the insulating films for forming a contact hole, such as TiN and the like, for the electrode material of the capacitor, is illustrated in the above-mentioned embodiment, the upper electrode, for example, may have a configuration, in which a layer of a material that exhibits higher etch selectivity to the insulating film for forming the contact hole such as a tungsten (W) film is formed on a TiN film and the like. Even in such case, a need for appropriately selecting etching conditions for forming the contact hole can be avoided by employing the configuration of forming the contact below the upper electrode, and therefore the procedure for manufacturing the semiconductor device can be simplified. In addition, damage to the upper electrode can be prevented, thereby providing a stable manufacture of the semiconductor device.

It is apparent that the present invention is not limited to the above embodiment, and may be modified and changed without departing from the scope and spirit of the invention.

What is claimed is:

1. A semiconductor device, comprising:
a semiconductor substrate;
a capacitor formed on said semiconductor substrate, said capacitor having a stacked structure including a lower electrode, a capacitive film and an upper electrode, that are stacked in this sequence;
an extracting unit of said upper electrode of said capacitor; and
a first contact formed under said extracting unit, and providing an electrical coupling between said extracting unit and a first underlying interconnect.

2. The semiconductor device according to claim 1, wherein said extracting unit is formed in the same layer as said upper electrode.

3. The semiconductor device according to claim 1, wherein said extracting unit is composed of the same material that is also employed for forming said upper electrode.

4. The semiconductor device according to claim 2, wherein said extracting unit is composed of the same material that is also employed for forming said upper electrode.

5. The semiconductor device according to claim 1, wherein said upper electrode and said extracting unit are composed of one selected from the group consisting of: TiN; a layered structure of Ti/TiN; TaN; WN; Pt; Ru; and polysilicon.

6. The semiconductor device according to claim 2, wherein said upper electrode and said extracting unit are composed of one selected from the group consisting of: TiN; a layered structure of Ti/TiN; TaN; WN; Pt; Ru; and polysilicon.

7. The semiconductor device according to claim 1, wherein said first underlying interconnect is composed of one selected from the group consisting of: a word line; a bit line; and an impurity-diffused region.

8. The semiconductor device according to claim 1, further comprising:
a first insulating film formed on said semiconductor substrate; and
a second contact, formed in said first insulating film, and providing an electrical coupling between said lower electrode of said capacitor and a second underlying interconnect,
wherein said first contact is formed in said first insulating film so as to be parallel to said second contact.

9. The semiconductor device according to claim 7, further comprising:
a first insulating film formed on said semiconductor substrate; and
a second contact, formed in said first insulating film, and providing an electrical coupling between said lower electrode of said capacitor and a second underlying interconnect,
wherein said first contact is formed in said first insulating film so as to be parallel to said second contact.

10. The semiconductor device according to claim 1, further comprising a second insulating film formed on said semiconductor substrate, wherein said capacitor is provided in a first concave portion formed in said second insulating film, and said extracting unit is provided in a second concave portion formed in said second insulating film so as to be parallel to said first concave portion.

11. The semiconductor device according to claim 1, further comprising a logic unit including a transistor formed in a region which is different from the region where said capacitor is formed, on said semiconductor substrate.

12. The semiconductor device according to claim 1, wherein said first underlying interconnect is formed at a level lower than that of said lower electrode of said capacitor.

13. A method for manufacturing a semiconductor device, including:
forming an insulating film on an underlying interconnect that is formed on a surface of or above a semiconductor substrate;
forming a contact in said insulating film, said contact being electrically coupled to said underlying interconnect;
forming a multiple-layered structure in a region on said insulating film which is different from the region where said contact is formed, said multiple-layered structure being composed of a lower electrode and a capacitive film, which are stacked in this sequence; and
forming an upper electrode material on said insulating film, said upper electrode material covering said capacitive film and being coupled to said contact.

14. The method for manufacturing the semiconductor device according to claim 13, wherein said forming the multiple-layered structure further includes:
forming said lower electrode and said capacitive film on the region where said contact is formed; and
selectively removing said capacitive film formed on the region where said contact is formed, and
wherein said upper electrode material is formed after said removing the capacitive film.

15. The method for manufacturing the semiconductor device according to claim 14, wherein, in said selectively removing the capacitive film in said forming the multiple-layered structure, said lower electrode formed on the region where said contact is formed is also selectively removed together with said capacitive film.
